(19) United States
(12) Patent Application Publication
(10) Pub. No.: US 2022/0005845 A1
(43) Pub. Date: Jan. 6, 2022

(54) CMOS-COMPATIBLE SHORT WAVELENGTH PHOTODETECTORS

(71) Applicants: Bardia Pezeshki, Mountain View, CA (US); Robert Kalman, Mountain View, CA (US); Cameron Danesh, Mountain View, CA (US)

(72) Inventors: Bardia Pezeshki, Mountain View, CA (US); Robert Kalman, Mountain View, CA (US); Cameron Danesh, Mountain View, CA (US)

(21) Appl. No.: 17/367,177

(22) Filed: Jul. 2, 2021

Related U.S. Application Data
(60) Provisional application No. 63/047,694, filed on Jul. 2, 2020.

(51) Int. Cl. H01L 27/144; H01L 31/02; H01L 31/0224; H01L 31/0232; H01L 31/105; H01L 31/18; G02B 6/42

(52) U.S. Cl. CPC H01L 27/1446; H01L 31/02019; H01L 31/022408; G02B 6/4214; H01L 31/105; H01L 31/1804; G02B 6/42; H01L 31/02327

(57) ABSTRACT

A lateral p-i-n photodetector may be made using CMOS compatible processes. CMOS circuitry may be included on a die including the lateral p-i-n photodetector. The lateral p-i-n photodetector may be formed in a device layer of the die, with a buried oxide under the device layer. P-type implants may bound a region defined by the lateral p-i-n photodetector.

### CROSS-REFERENCE TO RELATED APPLICATIONS

This application claims the benefit of U.S. Provisional Patent Application No. 63/047,694, filed on Jul. 2, 2020, the disclosure of which is incorporated by reference herein.

### FIELD OF THE INVENTION

The present invention relates generally to photodetectors, and more particularly to photodetectors for communication systems.

### BACKGROUND OF THE INVENTION

As semiconductor integrated circuits become more complex and run at higher speeds, there is increasing desire for efficient information flow between different parts of an IC, or even between a number of chips (or chiplets). This can be as simple as clock distribution, or more complex data transfer between processor and memory, or different logic blocks exchanging data.

Signaling within an IC or between ICs is almost always done electrically through the numerous metal levels formed lithographically above the IC (redistribution layers (RDLs) and back end of line (BEOL) layers), wiring in the package, the use of an interposer or bridge (typically fabricated from silicon or an organic laminate) inserted between the ICs and the package, the use of a printed circuit board to which multiple packaged ICs are attached, or the use of electrical cables between circuit boards within a chassis or in different chassis. However, electrical connections can suffer from signal integrity issues, including crosstalk, roll-off with frequency, and reflections at impedance discontinuities. Amelioration of the signal integrity issues may require signal regeneration and equalization, increasing circuit area and power requirements for the ICs. Additionally, power consumption generally scales with frequency, as each logic transition charges or discharges a potentially significant capacitance associated with the electrical line.

There has been a great deal of interest over several decades in using optics for clock distribution or intra- and inter-chip data distribution. For example, a synchronizing clock signal can be optically distributed with almost zero latency to many parts of a chip or a collection of chips that are co-packaged simultaneously. The optical signal can be sent through free-space, with possibly the use of mirrors or microlenses, or distributed in a waveguiding layer that is incorporated on the chip or in the package. In a more complex implementation, the data bus can be optical, connecting multiple points on the chips with optical signals.

Optical communication within a chip or between a set of chips requires appropriate optical sources and receivers. In silicon photonics, heterogeneously integrated lasers, co-packaged lasers, or an external laser is used to generate the light, while various modulator structures such as rings, Mach-Zehnder waveguide devices, or other components impose data on the CW signals. Detectors can be monolithically made in silicon by using absorbing germanium layers. Generally, a longer wavelength of 1.3 um is used for silicon photonics as it is compatible with fibers that send or receive the data elsewhere.

Generally, most photodetectors in silicon and other materials employ a p-i-n structure, where a lightly doped “intrinsic” semiconductor is sandwiched between p-doped and n-doped material. Either the built-in voltage of the diode alone or with the additional reverse bias causes an electric field to be present in the intrinsically doped “i” region. When photons are absorbed in this region and generate electron hole pairs, the electric field separates the two carriers and generates photocurrent.

Generally, p-i-n structures are made “vertically” (e.g., normal to the top surface of an IC), for example there is a top p-type region, with an intrinsic region below and all on top of n-type material. The photons have to pass through the top p-type region to be absorbed in the intrinsic region. This is not much of a problem at longer wavelengths because the absorption length of those wavelengths in Si is relatively long, and the top p-type region can thus be made quite thin compared to the absorption length of the light. But at shorter wavelengths where the absorption length in Si is much shorter, it is quite difficult to make the top p-region thin enough to be totally transparent. Any light that is absorbed in the top p-type region generally does not lead to photocurrent, as there is no electric field to separate the carriers. Any photogenerated carriers that appear in the top p-doped region generally recombine in the same region and are not detected.

Furthermore, there is a trade-off in vertical photodiodes between speed and efficiency. If the middle intrinsic region is made too thin compared to the absorption length of the photon wavelength, then not much of the light is absorbed. If is made too thick, such that all the light is absorbed, the region might be too wide for fast response; any photogenerated carriers generally should be swept out of the intrinsic region and even at saturated carrier velocities, transiting a wide intrinsic region causes a time delay and a reduction in speed.

It is frequently desirable to integrate photodiodes with CMOS electronics. However, vertical structures are generally not compatible with CMOS processes, nearly all of which are lateral surface processes on extremely thin layers.

A typical CMOS process follows the following steps. A relatively insulating wafer with low levels of doping is used and n-well and p-wells are implanted for the PMOS and NMOS structures. A thin oxide is grown to act as the gate oxide. Then a polysilicon layer is deposited and patterned to act as the gates. A second mask of photoresist blocks the p-well, while a p+ implant is used to form the source and the drain on the NMOS structure on the n-well. This mask is then removed and another photoresist mask is formed to protect the n-well, and a subsequent n+ implant is used to form the source and the drain on the NMOS structure made in the p-well. Then the resist is removed, silicided contacts are formed, and other lasers of oxide of PSG glass are made in the structure with different layers of interconnect metal.

### BRIEF SUMMARY OF THE INVENTION

In some embodiments a photodetector for short wavelength applications is fabricated in a fully CMOS compatible process. In some embodiments the photodetector does not include germanium or SiGe. In some embodiments the photodetector is for use with light with a wavelength much shorter than 1300 nm. In some such embodiments the photodetector is for use with blue light in the visible spectrum. In some embodiments the photodetector is for use with light with a wavelength of in the 400 nm-450 nm range, which may be transmitted through oxide, nitride or dielectric waveguides or fibers, and can be detected or absorbed in silicon easily, without the use of germanium. In some embodiments n+ and p+ regions of the photodetector are formed as part of a process of forming source and drain regions of NMOS and PMOS transistors for the photodetector. In some embodiments the n+ and p+ regions of the photodetector have implant diffusion depths of the source and drain regions of the NMOS and PMOS transistors. In some embodiments an oxide layer is provided below diffusions depths of the n+ and p+ regions of the photodetector.

Some embodiments provide a device including a CMOS compatible photodetector, comprising: a device layer including a photodetector region comprised of interdigitated p fingers and n fingers of a lateral p-i-n photodetector, the p fingers being connected to a p contact and the n fingers being connected to an n contact, the n fingers being doped with an n-type dopant and the p fingers being doped with a p-type dopant; and at least one of a buried oxide layer below the device layer, a buried doped layer below the device layer, or a p-type or n-type dopant implant at at least one edge of the photodetector region. In some embodiments the at least one of the buried oxide layer below the device layer, the buried doped layer below the device layer, or the p-type or n-type implant at at least one edge of the photodetector region comprises the buried oxide layer below the device layer. In some embodiments. In some embodiments the buried oxide layer is reflective at a wavelength of operation. In some embodiments the wavelength of operation is about 450 nm. In some embodiments a thickness of the device layer is between 3 and 5 times an absorption length of light at the wavelength of operation. In some embodiments doped regions for the p fingers and the n fingers extend at least halfway through the thickness of the device layer. In some embodiments the at least one of a buried oxide layer below the device layer or a p-type implant or n-type implant at at least one edge of the photodetector region further comprises the p-type implant or n-type implant at at least one edge of the photodetector region. In some embodiments the p-type implant or n-type implant at at least one edge of the photodetector region comprises p-type implants or n-type implants at at least opposing edges of the photodetector region. Some embodiments further comprise at least one PMOS transistor and at least one NMOS transistor in the device layer. In some embodiments the at least one of the buried oxide layer below the device layer, the buried doped layer below the device layer, or the p-type implant or n-type implant at at least one edge of the photodetector region comprises the buried doped layer below the device layer. In some embodiments the buried doped layer comprises an n-type doped layer. In some embodiments the buried doped layer comprises an p-type doped layer. Some embodiments further comprise transimpedance amplifier circuitry in the device layer. Some embodiments further comprise a waveguide positioned to provide light to the photodetector region.

Some embodiments provide a device including a CMOS compatible photodetector, comprising: a device layer including a photodetector region comprised of interdigitated p fingers and n fingers of a lateral p-i-n photodetector, the p fingers being connected to a p contact and the n fingers being connected to an n contact, the n fingers being doped with an n-type dopant and the p fingers being doped with a p-type dopant; and a photodetector isolation structure for the photodetector region. In some embodiments the photodetector isolation structure comprises a buried oxide layer below the device layer under the photodetector region. In some embodiments the photodetector isolation structure comprises a buried doped layer below the device layer under the photodetector region. In some embodiments the photodetector isolation structure comprises doped implants at opposing edges of the photodetector region. In some embodiments the photodetector isolation structure comprises a buried oxide layer below the device layer under the photodetector region and doped implants at opposing edges of the photodetector region.

These and other aspects of the invention are more fully comprehended upon review of this disclosure.

### BRIEF DESCRIPTION OF THE FIGURES

FIGS. 1A-I show a process flow of a detector region together with PMOS and NMOS transistors, in accordance with aspects of the invention.

FIGS. 2A and 2B show a vertical structure and a top view, respectively, of example interdigitated contacts of p+ and n+ with lightly doped semiconductor in between, in accordance with aspects of the invention.

FIG. 3 shows a cross-section of an example commonly formed p-i-n lateral photodetector and CMOS transistors with a waveguide extending over a region of the photodetector, in accordance with aspects of the invention.

FIG. 4 shows a cross section of a die including a photodetector/TIA combination with a waveguide on a back side of the photodetector, in accordance with aspects of the invention.

### DETAILED DESCRIPTION

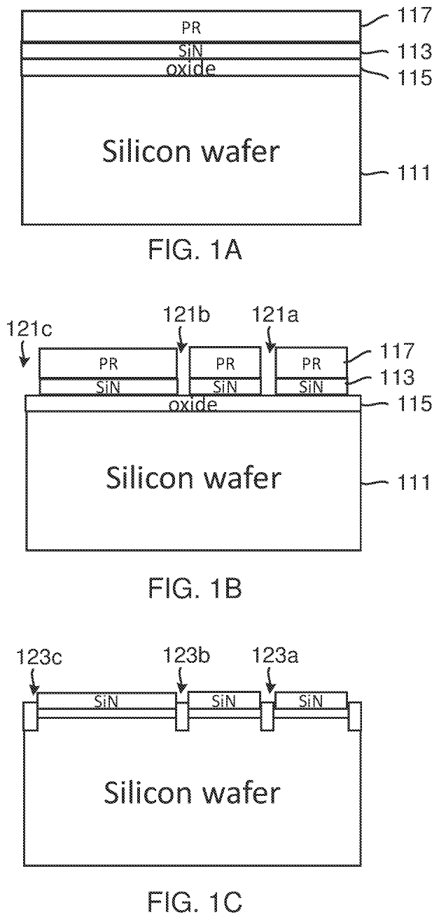

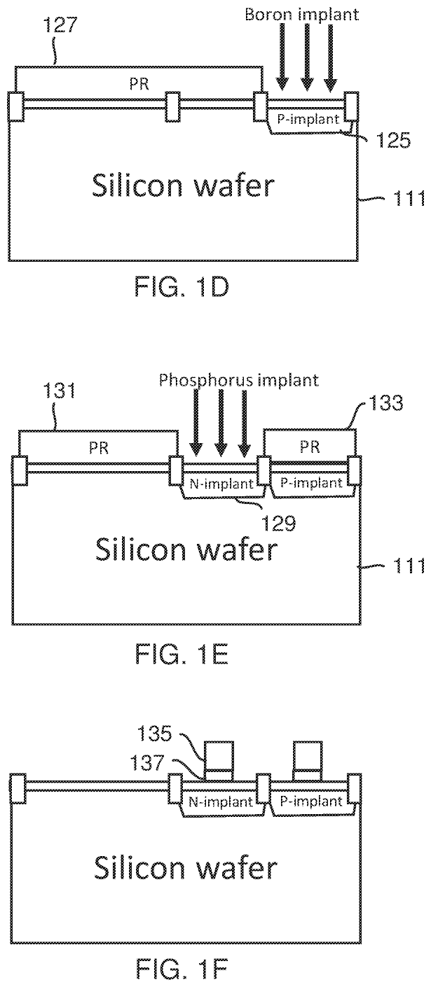

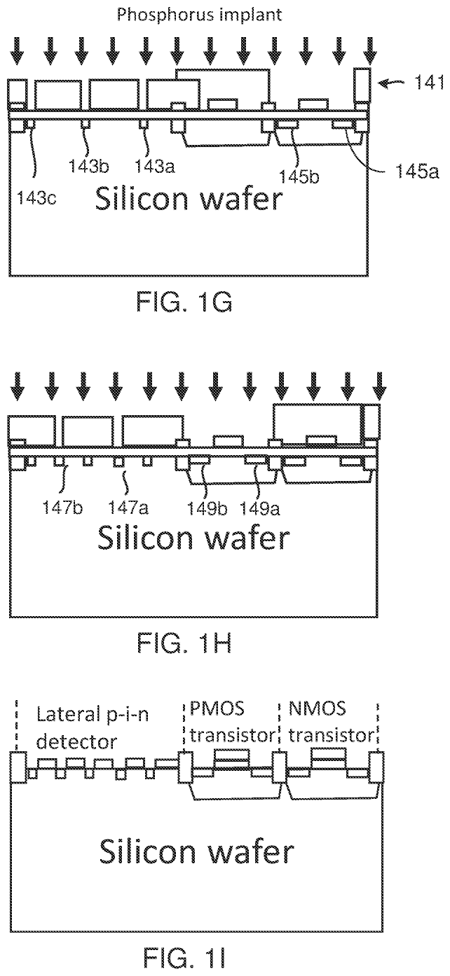

FIGS. 1A-I show a process flow of a detector region together with PMOS and NMOS transistors. Like a normal CMOS process, the process begins with a lightly doped silicon wafer 111 with a silicon nitride (SiN) top coating 113 on a thin layer of oxide 115, as illustrated in FIG. 1A. FIG. 1A also shows a photoresist layer 117 on top of the SiN top coating. The silicon nitride layer is patterned 121a-c with the photoresist and etched, down to the oxide layer as shown in FIG. 1B. An oxidation step using a local oxidation of silicon (LOCOS) process causes the exposed areas to have much thicker oxide 123a-c, that provides increased isolation between the different areas of the device, as shown in FIG. 1C. A p-type implant, for example a boron implant, is provided to form P-wells 125 of the NMOS regions. Photoresist 127 is used to block a p-type implant, for example so that the implant is only allowed to penetrate the wafer where NMOS transistors are formed, as shown in FIG. 1D. The process is repeated with an N-type implant, for example a phosphorous implant, to form the N-wells 129 of the PMOS regions, with photoresist 131, 133 used to block the n-type implant, for example as shown in FIG. 1E. Note that both these implants are blocked by photoresist 127 and 131 in a photodetector region.

Then a polysilicon layer 137 is deposited and patterned by photoresist 135 and etched to form the gate oxide, for example as shown in FIG. 1F. Gates are used for both the PMOS and NMOS regions, but all the polysilicon is removed from the detector region. The wafer is then patterned again with photoresist 141 to block an n-type implant, for example a phosphorous implant, on the PMOS transistor, while the polysilicon blocks the implant around the gate and drain regions of the NMOS transistor in a self-aligned process. In the detector region, the photoresist is patterned to form openings for the n-fingers of the lateral p-i-n photodetector. The n-type implant forms the source and drain regions 145a,b of the NMOS transistor and at the same time forms the n+ regions 143a-c of the photodetector, for example as shown in FIG. 1G. A similar process is used for a p-type implant, such as Boron, to form source and drain contacts 149a,b of the PMOS transistor and at the same time form the p+ regions 147a,b of the photodetector, for example as shown in FIG. 1H. With the source and drain regions of the transistors formed in the same manner as the p+ and n+ regions of the photodetector, the source and drain regions of the transistors have a similar implant depth as the p+ and n+ regions of the photodetector. Any remaining photoresist is removed, resulting in a lateral p-i-n detector adjacent a PMOS and NMOS transistor, for example as shown in FIG. 1I.

The above process produces interdigitated contacts of p+ and n+ with lightly doped semiconductor in between, and gate oxide above. In some embodiments, the interdigitated contacts are subsequently metalized. This can be accomplished by patterning the oxide to allow electrical contact to the source, drain and p and n regions of the lateral p-i-n detector. Ti can then be added, forming titanium silicide on the contacts and then following with additional metallization such as copper or gold.

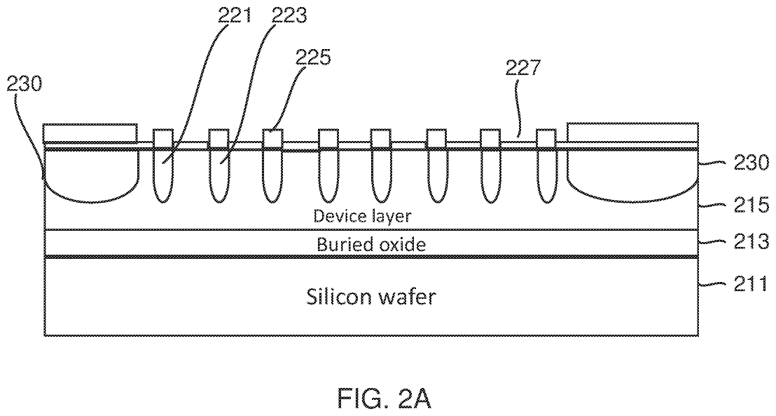

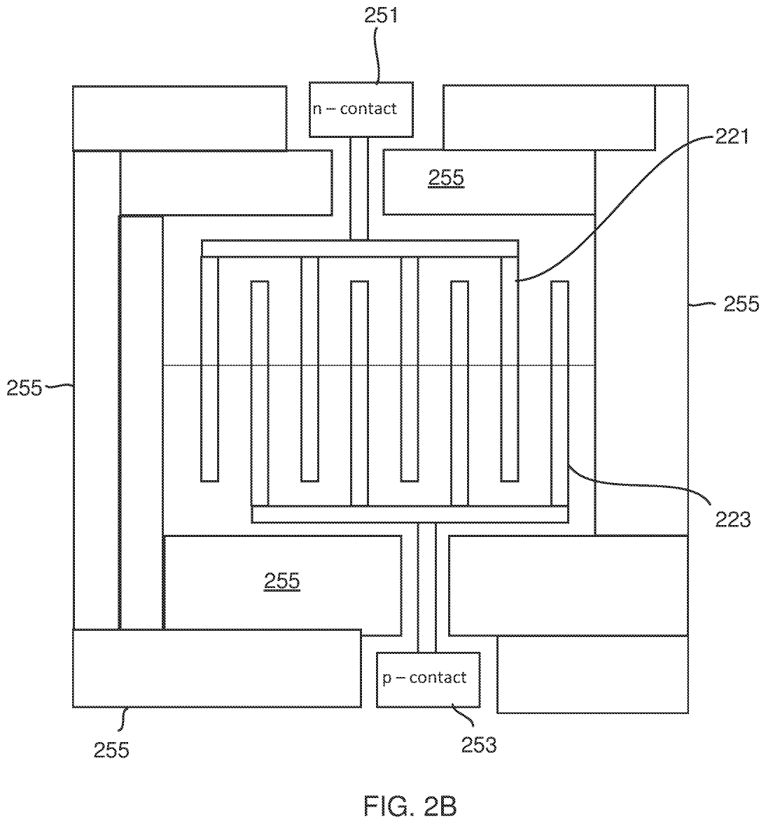

FIG. 2A shows a vertical structure and FIG. 2B shows a top view of example interdigitated contacts of p+ and n+ with lightly doped semiconductor in between. As may be seen in FIG. 2A, a silicon wafer 211 includes a device layer 215 about its upper portion. The device layer includes n-fingers 221 interspersed with p-fingers. The n-fingers may be made at the same time as source and drain contacts of an NMOS transistor, for example as discussed with respect to FIGS. 1A-I. Similarly, the p-fingers may be made at the same time as source and drain contacts of a PMOS transistor, also for example as discussed with respect to FIGS. 1A-I. The n-fingers and the p-fingers are part of a lateral p-i-n photodetector. The p-fingers are connected to a p-contact 253, and the n-fingers are connected to an n-contact 251 When the device is reverse biased, the intrinsic region is depleted and an electric field sweeps out the carriers. Typical distance between the fingers would be one micron, while finger width would be minimized to be 0.5 um or less. In some embodiments, areas between the fingers may have an anti-reflective coating 227, for example an oxide anti-reflective coating. Any light that falls on the fingers does not generate a photocurrent. If the fingers are metalized 225, this is because the light is reflected or absorbed by the metal. Even if the fingers are unmetallized, there is no significant electric field in doped regions and thus any photogenerated carriers are not separated and do not generate photocurrent.

The addition of a buried oxide layer 213 increases the speed of the photodetector because any carriers generated deep within the wafer are not collected. The buried oxide layer is shown in FIG. 2A (and other figures) as being at least vertically under a photodetector region. The electric field is weak deep down in the semiconductor, so any deep carriers are not swept out fast and would generate a slow tail on the photodetector response if collected; the buried oxide prevents these slow, deep carriers from being collected. In some embodiments thickness of the buried oxide layer is reflective at a wavelength of light incident on the photodetector. Any light that reaches the buried oxide layer and is reflected may be subsequently absorbed, increasing the photodetector's quantum efficiency. In some embodiments thickness of the buried oxide layer is reflective at a wavelength of operation. In some embodiments thickness of the buried oxide layer is reflective for at least some wavelengths equal to n/2*(buried oxide layer thickness)/(oxide refractive index), where n is an integer and wavelength is expected wavelength of light incident on the photodetector.

In some embodiments, the photodetector structure comprises a buried doped layer instead of a buried oxide layer. This buried doped layer may be fabricated as an n-type implant or p-type implant. This layer serves a similar purpose to that of a buried oxide layer: any carriers generated deeper than the layer are not collected by p-i-n detector structure. In some embodiments, the buried doped layer may not be electrically connected to other structures such that it is electrically floating. In some embodiments, a p-type buried implant layer may touch the p-type fingers of the photodetector. In some embodiment, an n-type buried implant layer may touch the n-fingers of the photodetector such that it is at the same voltage as the n-type fingers.

Similarly, preferably the detector is not illuminated outside the region of the fingers. For this reason, it is preferred both to block off the light away from the finger region with metal 255, for example, and also dope the regions 230 outside, in some embodiments at edges of, the detector, for example with a p-type implant, although in some embodiments an n-type implant may be used. This is shown in FIG. 2A where doping is outside the fingers. The buried oxide layer, the buried doped layer, and the edge implants, individually or in various combinations, can be considered a photodetector isolation structure.

The detector quantum efficiency (QE) is simple to calculate. Generally, factors impacting QE include:

1. Surface reflectivity: Ideally the thickness of the oxide 227 is appropriate to act an as anti-reflection coating layer. Other materials, such as MgF, SiN, or other dielectric, can be deposited on the detector surface to act as an anti-reflective (AR) coating and reduce the light that is lost simply through reflection.

2. The “duty cycle” of the fingers: The finger “duty cycle” is the ratio of spacing between the fingers to the center-to-center finger spacing. As previously mentioned, light that is incident on the fingers is lost, and thus maximizing duty cycle maximizes QE.

3. Thickness of the silicon device region: Ideally this is a few times the absorption length of the light in silicon. For example, at 450 nm, the absorption length of light in silicon is about 0.2 um. Preferably the device layer should be a few times this, or say 0.6 to 1 um for vertical incidence. For proper collection of carriers, the doped region should penetrate a substantial region into the absorption region. Otherwise, there will be only weak electric fields in the lower parts of the wafer and the carriers generated there will not be efficiently collected.

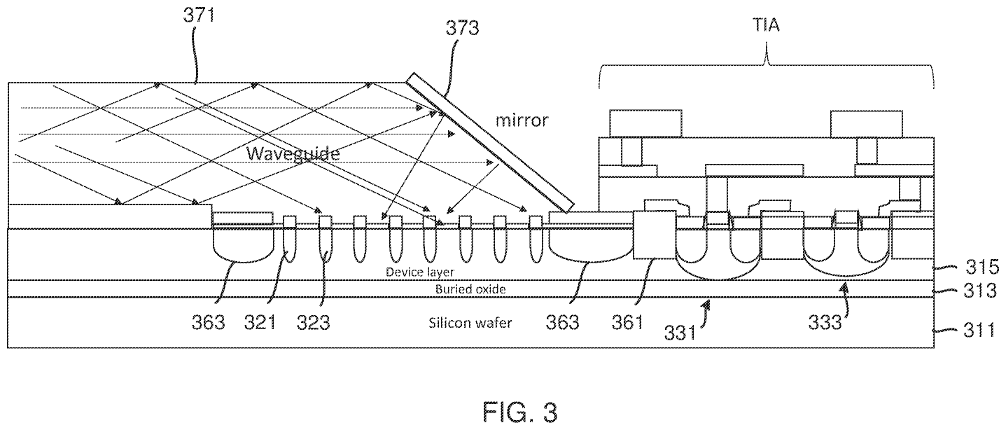

In some embodiments, a waveguide is fabricated on top of a detector. FIG. 3 shows a cross-section of an example commonly formed p-i-n lateral photodetector and CMOS transistors with a waveguide extending over a region of the photodetector. As discussed with respect to FIGS. 1A-I and FIG. 2, n-fingers 321 and p-fingers 323 of the photodetector are interspersed in a device layer 315 of a silicon wafer 311. A PMOS transistor 331 and an NMOS transistor 333 are also in the device layer. The transistors may be part of a transimpedance amplifier (TIA), for example. FIG. 3 showing the transistors separated from the photodetector region by an isolation oxide 361 and a p-type doped implant 363 at an edge of the photodetector region. A buried oxide layer 313 is below the device layer. The buried oxide layer may, for example, increase speed of the photodetector, for example as discussed with respect to FIG. 2. In some embodiments, the photodiode structure may comprise a buried doped layer rather than a buried oxide layer. A waveguide core layer 371 is deposited on the substrate containing the detector; polymer or silicon nitride are typical choices. The core layer is selectively etched to leave waveguides, and these waveguides may be operating in the multimode or single-mode regime. Compared to embodiments where the light is incident normal to the detector, the thickness of the device layer (approximately the depth of the finger dopant implants) of the detector can be much smaller when used with a waveguide without significantly impairing the detector efficiency. In some embodiments, a bottom cladding layer of a low index material 370 such as silicon dioxide may be deposited on the surface of the substrate prior to depositing the core layer. However, any lower cladding layer is removed in the active area of the detector.

In some embodiments, the waveguide and detector are in contact over a sufficient length that most of the light in the waveguide is absorbed along the length of the detector. As light propagating in the waveguide enters the region where the waveguide is in contact with the detector, some of the light is absorbed in the detector because the detector index is higher than that of the waveguide core. Light that is not directly absorbed is reflected and absorbed farther down the waveguide when it again encounters the core-detector interface.

In some embodiments, the waveguide is terminated by a reflective coating 373 (such as a metal layer) that forms an angled mirror at the end of the waveguide. Light reflected from this mirror is absorbed by the photodetector. Such an angled mirror can easily be formed by under-etching a material with a mask and metallizing afterwards. An under-cut forms under a mask and the angle can be adjusted by varying the directionality, pressure, and reactant concentration in the etch. Similarly, a grey scale mask or nano-imprint technology can be used.

In some embodiments, the detector is monolithically integrated with a transimpedance amplifier (TIA) and/or other active electronics. In some embodiments, this detector/TIA combination is fabricated in the same substrate on which the waveguides are fabricated.

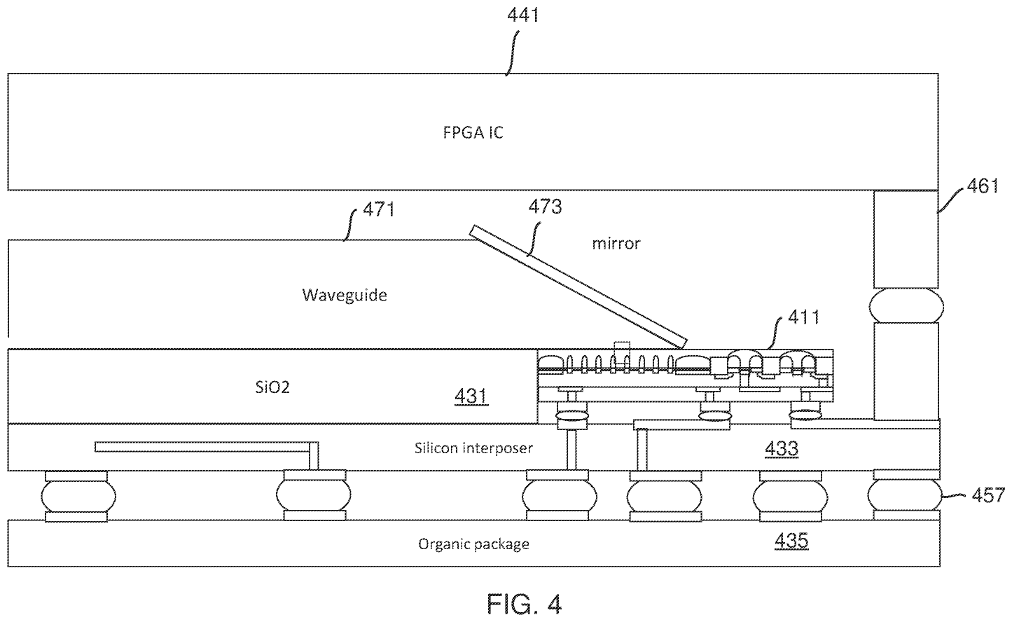

In some embodiments, the detector/TIA die are fabricated on a silicon wafer with a buried oxide layer, and the die may have been released from that wafer using a selective etch in which the buried oxide acts as an etch-stop layer and allows the die to be lifted off that wafer. FIG. 4 shows a die 411 containing a photodetector/TIA combination flip-chip bonded to a different substrate containing the waveguides 471 and other optical elements. The waveguides may be over a portion of the die including the photodetector, and, as illustrated in FIG. 4, may extend on a silicon dioxide layer, for example to other chips. As with the embodiment of FIG. 3, the waveguide may terminate in an angled mirror 473, which reflects light in the waveguide towards the photodetector. In this configuration, light is incident on the photodetector from the back side (the buried oxide side rather than the top surface of the silicon).

In some embodiments, the substrate to which the detector/TIA die is attached is a silicon interposer 433. In some embodiments, the substrate is designed to be used between a complex logic or memory IC, such as a FPGA or a GPU and a package and has thin wiring and through-chip vias. The output signal from the TIA is transmitted to a logic chip 441 above, or sent down through the interposer to the package 435 below.

Various interconnect schemes can be used between this chip, the logic chip, and the package. Solder bumps 457, copper pillars 461, solid-liquid diffusion bonding, or other methods. An advantage of course is that the optical signal in the waveguide can propagate longer distances without cross-talk or degradation than electrical lines.

Although the invention has been discussed with respect to various embodiments, it should be recognized that the invention comprises the novel and non-obvious claims supported by this disclosure.

What is claimed is:

1. A device including a CMOS compatible photodetector, comprising:
a device layer including a photodetector region comprised of interdigitated p fingers and n fingers of a lateral p-i-n photodetector, the p fingers being connected to a p contact and the n fingers being connected to an n contact, the n fingers being doped with an n-type dopant and the p fingers being doped with a p-type dopant; and
at least one of a buried oxide layer below the device layer, a buried doped layer below the device layer, or a p-type or n-type dopant implant at at least one edge of the photodetector region.

2. The device of claim 1, wherein the at least one of the buried oxide layer below the device layer, the buried doped layer below the device layer, or the p-type or n-type implant at at least one edge of the photodetector region comprises the buried oxide layer below the device layer.

3. The device of claim 2, wherein the buried oxide layer is reflective at a wavelength of operation.

4. The device of claim 3, wherein the wavelength of operation is about 450 nm.

5. The device of claim 4, wherein a thickness of the device layer is between 3 and 5 times an absorption length of light at the wavelength of operation.

6. The device of claim 5, wherein doped regions for the p fingers and the n fingers extend at least halfway through the thickness of the device layer.

7. The device of claim 6, wherein the at least one of a buried oxide layer below the device layer, buried doped layer below the device layer, or a p-type implant or n-type implant at at least one edge of the photodetector region further comprises the p-type implant or n-type implant at at least one edge of the photodetector region.

8. The device of claim 7, wherein the p-type implant or n-type implant at at least one edge of the photodetector region comprises p-type implants or n-type implants at at least opposing edges of the photodetector region.

9. The device of claim 8, further comprising at least one PMOS transistor and at least one NMOS transistor in the device layer.

10. The device of claim 1, wherein the at least one of the buried oxide layer below the device layer, the buried doped layer below the device layer, or the p-type implant or n-type implant at at least one edge of the photodetector region comprises the buried doped layer below the device layer.

11. The device of claim 10, wherein the buried doped layer comprises an n-type doped layer.

12. The device of claim 10, wherein the buried doped layer comprises an p-type doped layer.

13. The device of claim 8, further comprising transimpedance amplifier circuitry in the device layer.

14. The device of claim 1, further comprising a waveguide positioned to provide light to the photodetector region.

15. A device including a CMOS compatible photodetector, comprising:
a device layer including a photodetector region comprised of interdigitated p fingers and n fingers of a lateral p-i-n photodetector, the p fingers being connected to a p contact and the n fingers being connected to an n contact, the n fingers being doped with an n-type dopant and the p fingers being doped with a p-type dopant; and
a photodetector isolation structure for the photodetector region.

16. The device of claim 15, wherein the photodetector isolation structure comprises a buried oxide layer below the device layer under the photodetector region.

17. The device of claim 15, wherein the photodetector isolation structure comprises a buried doped layer below the device layer under the photodetector region.

18. The device of claim 15, wherein the photodetector isolation structure comprises doped implants at opposing edges of the photodetector region.

19. The device of claim 15 wherein the photodetector isolation structure comprises a buried oxide layer below the device layer under the photodetector region and doped implants at opposing edges of the photodetector region.

20. The device of claim 15 wherein the photodetector isolation structure comprises a buried doped layer below the device layer under the photodetector region and doped implants at opposing edges of the photodetector region.
